(19) United States
(12) Patent Application Publication
(10) Pub. No.: US 2023/0389209 A1
(43) Pub. Date: Nov. 30, 2023

(54) DISPLAY DEVICE

(71) Applicant: Samsung Display Co., Ltd., Yongin-si (KR)

(72) Inventors: JOOHYEON LEE, Yongin-si (KR); MINHYUCK KANG, Yongin-si (KR); HYUN JOON OH, Yongin-si (KR)

(21) Appl. No.: 18/324,614

(22) Filed: May 26, 2023

(30) Foreign Application Priority Data
May 31, 2022 (KR) 10-2022-0066653

(51) Int. Cl. H05K 5/03

(52) U.S. Cl. CPC H05K 5/03

(57) ABSTRACT

Provided is a display device including a display panel, a shock-absorbing panel above the display panel, having a Young's modulus of about 700 MPa to about 1200 MPa with respect to a strain of about 0.025% to about 0.5%, and including a support film, and a buffer layer below the support film, and a window above the shock-absorbing panel, and including a glass substrate.

### CROSS-REFERENCE TO RELATED APPLICATION

This application claims priority to, and the benefit of, Korean Patent Application No. 10-2022-0066653, filed on May 31, 2022, in the Korean Intellectual Property Office, the entire contents of which are hereby incorporated by reference.

### BACKGROUND

### 1. Field

The present disclosure herein relates to a display device including a shock-absorbing panel.

### 2. Description of the Related Art

Various types of display devices are used to provide image information, and display devices including flexible display panels that are foldable or bendable have been recently developed. The flexible display devices, unlike rigid display devices, are variously modifiable in shape by being foldable, rollable, or bendable, and thus have portability without being limited to display screen sizes.

Such flexible display devices may suitably use a member that serves to protect a display panel and a window without hindering folding or bending operation.

### SUMMARY

The present disclosure provides a display device maintaining folding properties and having improved impact resistance. One or more embodiments of the present disclosure provides a display

device including a display panel, a shock-absorbing panel above the display panel, having a Young's modulus of about 700 MPa to about 1200 MPa with respect to a strain of about 0.025% to about 0.5%, and including a support film, and a buffer layer below the support film, and a window above the shock-absorbing panel, and including a glass substrate.

The support film may have a greater Young's modulus than the buffer layer. With respect to the strain, the support film may have a Young's modulus of about 1200 MPa to about 2000 MPa.

With respect to the strain, the buffer layer may have a Young's modulus of about 10 MPa to about 30 MPa.

The support film may be thicker than the buffer layer.

The buffer layer may have a thickness of about 20 μm to about 30 μm.

The support film may have a thickness of about 35 μm to about 45 μm.

The shock-absorbing panel may further include a sub support film above the support film.

The sub support film may have a greater Young's modulus than the support film and the buffer layer.

With respect to the strain, the sub support film may have a Young's modulus of about 3000 MPa to about 4000 MPa.

The sub support film may be thinner than the support film and the buffer layer.

The sub support film may have a thickness of about 5 μm to about 15 μm.

The shock-absorbing panel may have a thickness of about 60 μm to about 80 μm.

The window may have a thickness of about 10 μm to about 300 μm.

The display device may further include a protection layer above the window, wherein the protection layer includes at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cyclic olefin copolymer (COC).

In one or more embodiments of the present disclosure, a display device includes a display panel, a shock-absorbing panel above the display panel, having a Young's modulus of about 700 MPa to about 1200 MPa with respect to a strain of about 0.025% to about 0.5%, and including a support film including at least one of an amide-based resin, an ester-based resin, an ether-based resin, or a carbonate-based resin, and a buffer layer including at least one of an acryl-based resin, a urethane-based resin, or a silicone-based resin, and below the support film, and a window above the shock-absorbing panel and including a glass substrate.

The support film may have a greater Young's modulus than the buffer layer, and is thicker than the buffer layer.

The shock-absorbing panel may further include a sub support film above the support film and having a greater Young's modulus than the support film and the buffer layer.

The sub support film may include at least one of an imide-based resin or an aramid-based resin.

The display device may be folded to have a radius of curvature of about 1 mm to about 5 mm with respect to at least one folding axis.

### BRIEF DESCRIPTION OF THE DRAWINGS

The accompanying drawings are included to provide a further understanding of the present disclosure, and are incorporated in, and constitute a part of, this specification. The drawings illustrate embodiments of the present disclosure and, together with the description, serve to explain principles of the present disclosure. In the drawings:

FIG. 1A is a perspective view showing a state in which a display device according to one or more embodiments is unfolded;

FIG. 1B is a perspective view showing an in-folding process of the display device according to one or more embodiments shown in FIG. 1A;

FIG. 1C is a perspective view showing an out-folding process of the display device according to one or more embodiments shown in FIG. 1A;

FIG. 2 is a cross-sectional view showing a portion taken along the line I-I′ of FIG. 1A;

FIG. 3 is a cross-sectional view showing a portion taken along the line II-II′ of FIG. 1B;

FIG. 4 is a cross-sectional view showing a shock-absorbing panel according to one or more embodiments;

FIG. 5 is a cross-sectional view showing a shock-absorbing panel according to one or more embodiments;

FIG. 6 is a graph showing pen drop test results in Comparative Examples and Experimental Examples;

FIG. 7A is a window image taken through a microscope in Comparative Example; and

FIG. 7B is a window image taken through a microscope in Example.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a display device according to one or more embodiments of the present disclosure will be described with reference to the accompanying drawings.

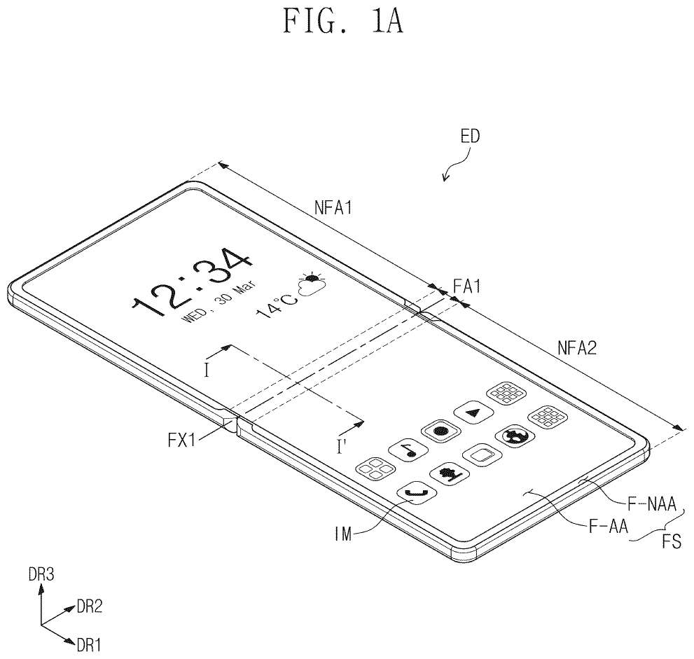

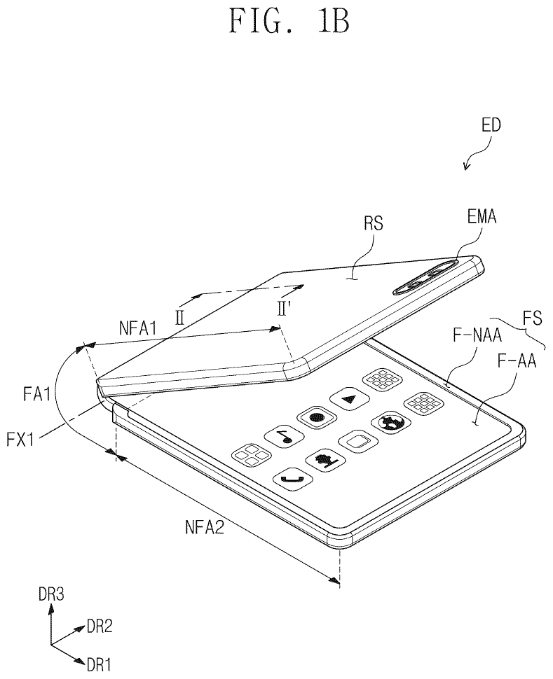

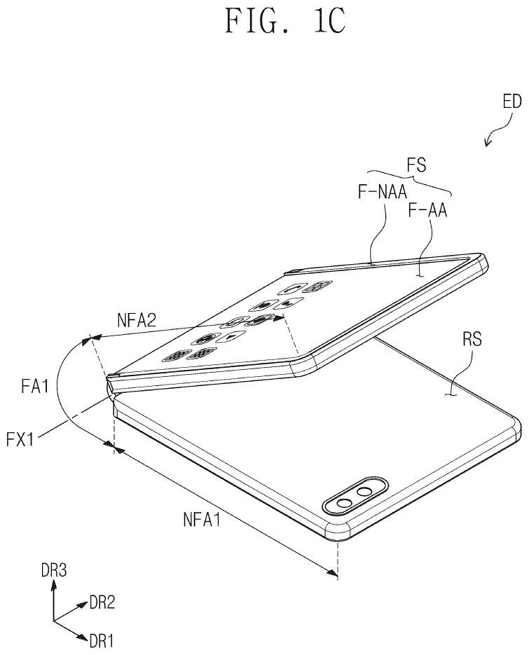

FIG. 1A is a perspective view showing a display device according to one or more embodiments, and showing a state in which the display device according to one or more embodiments is unfolded. FIG. 1B is a perspective view showing an in-folding process of the display device shown in FIG. 1A. FIG. 1C is a perspective view showing an out-folding process of the display device shown in FIG. 1A.

A display device ED may be a device activated according to electrical signals. For example, the display device ED may be a mobile phone, a tablet, a car navigation system, a game console, a personal computer, a laptop computer, or a wearable device, but is not limited thereto. In FIG. 1A, as an example, a mobile phone is presented as the display device ED.

Referring to FIGS. 1A to 1C, the display device ED may include a first display surface FS defined by a first directional axis DR1, and a second directional axis DR2 crossing the first directional axis DR1. The display device ED may provide an image IM to users through the first display surface FS. The display device ED according to one or more embodiments may display the image IM on the first display surface FS towards a third direction DR3 that is perpendicular to the first directional axis DR1 and to the second directional axis DR2. On a plane defined by the first directional axis DR1, and by the second directional axis DR2 crossing the first directional axis DR1, the display device ED may include a long side parallel to the first directional axis DR1, and a short side parallel to the second directional axis DR2. However, this is presented as an example, and the shape of the display device ED is not limited thereto.

As used herein, a front surface (or an upper surface) and a rear surface (or a lower surface) of respective members may be defined with respect to the first display surface FS, and a surface that is more adjacent to the first display surface FS may be defined as the front surface. Front and rear surfaces may oppose each other in the third directional axis DR3, and a normal direction of each of the front and rear surfaces may be substantially parallel to the third directional axis DR3. In some embodiments, as used herein, an upper side indicates a direction more adjacent to the front surface, a lower side indicates a direction more adjacent to the rear surface, and the upper side and the lower side are opposite to each other in the third directional axis DR3.

As used herein, the first directional axis DR1 and the second directional axis DR2 may be perpendicular to each other, and the third directional axis DR3 may be a normal direction to a plane defined by the first directional axis DR1 and the second directional axis DR2. A thickness direction of the display device ED may be parallel to the third directional axis DR3. Directions indicated by the first to third directional axes DR1, DR2, and DR3, as described herein, are relative concepts, and may thus be changed to other directions. In some embodiments, the directions indicated by the first to third directional axes DR1, DR2, and DR3 may be described as first to third directions, and the same reference numerals may be used.

The display device ED may include the first display surface FS and a second display surface RS. When the display device ED is unfolded, the first display surface FS may be viewed by users. When the display device ED is in-folded, the second display surface RS may be viewed by users. The first display surface FS may include an active region F-AA and a peripheral region F-NAA. The second display surface RS may include an electronic module region EMA. The second display surface RS may be defined as a surface opposite to at least a portion of the first display surface FS. For example, the second display surface RS may be defined as a portion of the rear surface of the display device ED.

The active region F-AA of the display device ED may be a region activated according to electrical signals. The display device ED may display the image IM through the active region F-AA. In some embodiments, the active region F-AA may detect one or more suitable forms of external inputs. The peripheral region F-NAA may be adjacent to the active region F-AA. The peripheral region F-NAA may have a color (e.g., a set or predetermined color). The peripheral region F-NAA may cover the active region F-AA. Accordingly, the shape of the active region F-AA may be substantially defined by the peripheral region F-NAA. However, the present disclosure is not limited thereto, and the peripheral region F-NAA may be located adjacent to only one side of the active region F-AA, or may be omitted.

The electronic module region EMA may have one or more suitable electronic modules located therein. For example, the electronic module may include at least one of a camera, a speaker, a light detection sensor, or a heat detection sensor. The electronic module region EMA may detect an external subject received through the first and second display surfaces FS and RS, or may provide sound signals, such as voice, to the outside through the first and second display surfaces FS and RS. The electronic module may include a plurality of components, and is not limited to any one embodiment.

The display device ED may include a folding region FA1 and non-folding regions NFA1 and NFA2. The non-folding regions NFA1 and NFA2 may be located adjacent to the folding region FA1 with the folding region FA1 therebetween. The display device ED may include a first non-folding region NFA1 and a second non-folding region NFA2, which are spaced apart with the folding region FA1 therebetween in the first direction DR1. For example, the first non-folding region NFA1 may be located at one side of the folding region FA1 in the second direction DR2, and the second non-folding region NFA2 may be located at the other side of the folding region FA1 in the second direction DR2.

FIGS. 1A to 1C shows one or more embodiments of the display device ED including one folding region FA1, but the present disclosure is not limited thereto. A plurality of folding regions may be defined in the display device ED. For example, the display device ED may include two or more folding regions, and three or more non-folding regions respectively located with a respective one of the folding regions therebetween.

Referring to FIG. 1B, the display device ED may be folded with respect to a folding axis FX1. The folding axis FX1 is a virtual axis extending in the second direction DR2, and the folding axis FX1 may be substantially parallel to a short side of the display device ED. In one or more other embodiments, the folding axis FX1 may be parallel to a long side of the display device ED. The folding axis FX1 may extend in the second direction DR2 along the first display surface FS. Although one folding axis FX1 is shown in FIGS. 1B and 1C, the number of folding axes is not limited to any one embodiment.

The display device ED may be folded with respect to the folding axis FX1 to become in-folded such that respective regions of the first display surface FS face each other. One region of the first display surface FS may be a region overlapping the first non-folding region NFA1 of the first display surface FS, and the other region of the first display surface FS may be a region overlapping the second non-folding region NFA2 of the first display surface FS.

Referring to FIG. 1C, the display device ED may be folded with respect to the first folding axis FX1 to become out-folded such that respective regions of the second surface region RS face each other. One region of the second display surface RS may be a region overlapping the first non-folding region NFA1 of the second display surface RS, and the other region of the second display surface RS may be a region overlapping the second non-folding region NFA2 of the second display surface RS.

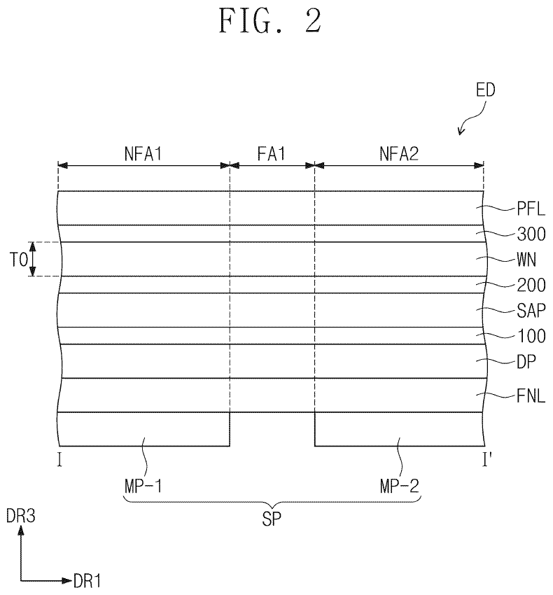

FIG. 2 is a cross-sectional view showing a portion taken along the line I-I′ of FIG. 1A. FIG. 2 is a cross-sectional view of a display device ED according to one or more embodiments.

The display device ED according to one or more embodiments may include a display panel DP, a shock-absorbing panel SAP located above the display panel DP, and a window WN located above the shock-absorbing panel SAP. In some embodiments, the display device ED may further include a functional layer FNL located below the display panel DP, a support member SP located below the functional layer FNL, and a protection layer PFL located above the window WN.

The support member SP may support components located above the support member SP. The support member SP may include a first support portion MP-1 and a second support portion MP-2, which are spaced apart from each other in the first direction DR1. The first support portion MP-1 and the second support portion MP-2 may be spaced apart from each other in the folding region FA1. In one or more embodiments, the support member SP may further include an electromagnetic wave shielding layer, a heat dissipation layer, and/or the like.

The functional layer FNL may include a single layer or multiple layers. The functional layer FNL may include at least one of a barrier film or a cushion layer. When the functional layer FNL includes a barrier film, the barrier film may include a synthetic resin film. When the functional layer FNL includes a cushion layer, the cushion layer may include foam or sponge. In some embodiments, the functional layer FNL may include a colored polyimide film. The functional layer FNL may prevent or reduce the likelihood of damage to the display panel DP during a manufacturing process. For example, the functional layer FNL may include an opaque yellow film.

The display panel DP may be an organic light emitting display panel, an inorganic light emitting display panel, a quantum dot display panel, a micro-LED display panel, a nano-LED display panel, or a liquid crystal display panel. The display panel DP may be folded with respect to at least one folding axis FX1 (FIG. 1A).

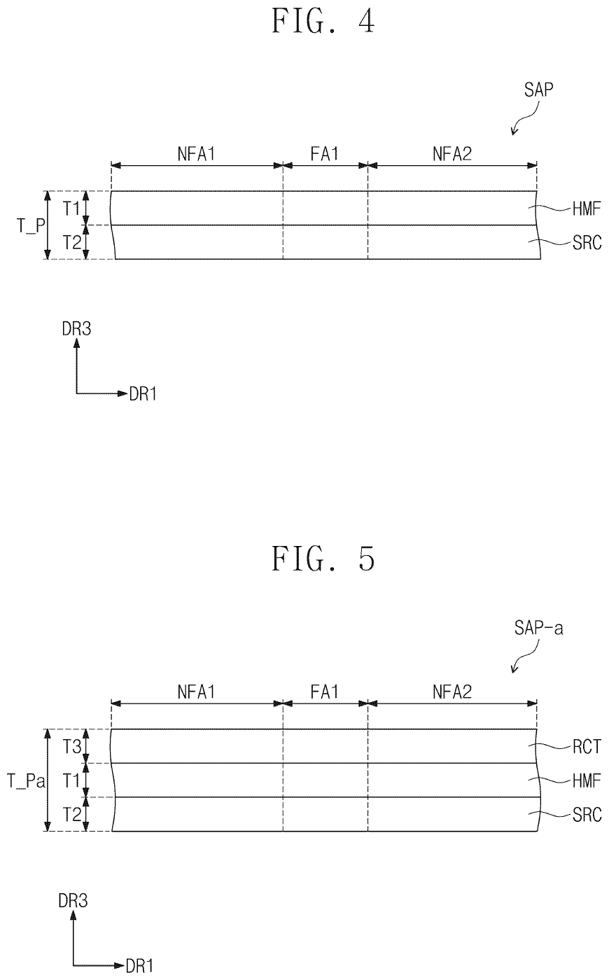

In one or more embodiments, the shock-absorbing panel SAP may have a Young's modulus of about 700 MPa to about 1200 MPa. As used herein, the Young's modulus indicates a modulus with respect to a strain of about 0.025% to about 0.5% at room temperature. The shock-absorbing panel SAP may absorb external shocks to protect the display panel DP and the window WN, which are respectively located below and above the shock-absorbing panel SAP. Accordingly, the display device ED according to one or more embodiments including the shock-absorbing panel SAP may exhibit improved impact resistance. The shock-absorbing panel SAP will be described in more detail later with reference to FIGS. 4 and 5.

The window WN may include a glass substrate. The window WN may include tempered glass. The window WN may have a thickness T0 of about 10 μm to about 300 μm. For example, the thickness T0 of the window WN may be about 30 μm to about 80 μm.

The protection layer PFL may transmit an image provided from the display panel DP as it is, and may protect the window WN from external shocks. For example, the protection layer may include at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cyclic olefin copolymer (COC). In one or more embodiments, the display device ED may further include an anti-fingerprint layer located above the protection layer PFL.

The display device ED may further include adhesive layers 100, 200, and 300 respectively located between the display panel DP and the shock-absorbing panel SAP, between the shock-absorbing panel SAP and the window WN, and between the window WN and the protection layer PFL. The first adhesive layer 100 may be located between the display panel DP and the shock-absorbing panel SAP. The second adhesive layer 200 may be located between the shock-absorbing panel SAP and the window WN. The third adhesive layer 300 may be located between the window WN and the protection layer PFL. However, the present disclosure is not limited thereto, and at least one of the first to third adhesive layers 100, 200, and 300 may be omitted.

Each of the first to third adhesive layers 100, 200, and 300 may include a typical adhesive or a pressure-sensitive adhesive. Each of the first adhesive layer 100, the second adhesive layer 200, and the third adhesive layer 300 may include a pressure sensitive adhesive (PSA), an optically clear adhesive film, and an optically transparent adhesive resin, and/or the like.

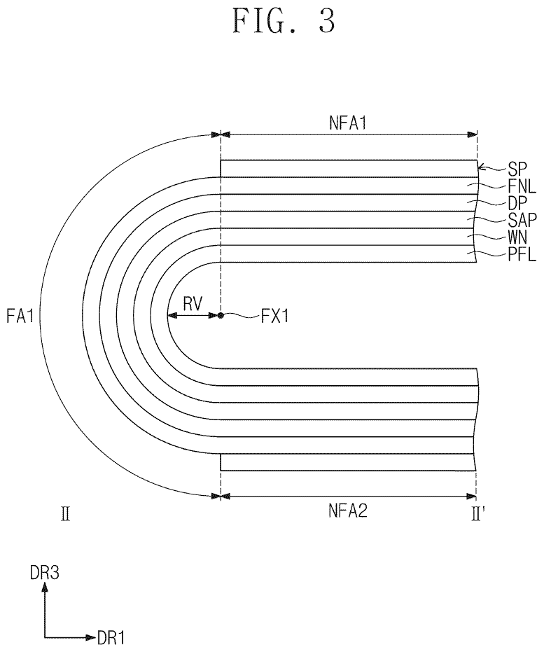

FIG. 3 is a cross-sectional view showing a portion taken along the line II-II′ of FIG. 1B. Referring to FIG. 3, the display device ED may be folded to have a radius of curvature RV (e.g., a set or predetermined radius of curvature RV) with respect to the folding axis FX1. For example, the radius of curvature RV may be about 1 mm to about 5 mm.

FIG. 4 is a cross-sectional view showing a shock-absorbing panel SAP according to one or more embodiments. FIG. 4 shows the shock-absorbing panel SAP shown in FIG. 2 in more detail.

In one or more embodiments, the shock-absorbing panel SAP may have a Young's modulus of about 700 MPa to about 1200 MPa. For example, the Young's modulus of the shock-absorbing panel SAP may be about 940 MPa to about 1100 MPa. A shock-absorbing panel having a Young's modulus of less than about 700 MPa may be more vulnerable to external shocks, and thus a window and a display panel located adjacent to the shock-absorbing panel may be more likely to be damaged. A shock-absorbing panel having a Young's modulus of greater than about 1200 MPa is not easy to repeat folding and unfolding. A shock-absorbing panel SAP having a Young's modulus of about 700 MPa to about 1200 MPa and a display device ED including the same may exhibit excellent or suitable impact resistance.

The shock-absorbing panel SAP according to one or more embodiments may have a thickness T_P of about 60 μm to about 80 μm. For example, the thickness T_P of the shock-absorbing panel SAP may be about 65 μm. A shock-absorbing panel having a thickness of less than about 60 μm is vulnerable to external shocks, and a shock-absorbing panel having a thickness of about 80 μm or greater makes a display device thicker. A shock-absorbing panel SAP having a thickness T_P of about 60 μm to about 80 μm may exhibit excellent or suitable impact resistance without a substantial increase in thickness. Improvement in impact resistance requires an increase in thickness of a shock-absorbing panel, but the shock-absorbing panel SAP according to one or more embodiments may exhibit excellent or suitable impact resistance without a substantial increase in thickness.

The shock-absorbing panel SAP may include a support film HMF, and a buffer layer SRC located below the support film HMF. The support film HMF may support the window WN. The support film HMF may minimize, prevent, or reduce the likelihood of damage to the window WN from external shocks. For example, when the window WN is cracked due to external shocks, the support film HMF may serve as a component to prevent or reduce the likelihood of the window WN sagging, and to increase resistance to damage to the window WN. The buffer layer SRC may absorb and disperse external shocks, and may prevent or reduce the likelihood of damage to the display panel DP located below.

The support film HMF may have a greater Young's modulus than the buffer layer SRC. The Young's modulus of the supporting film HMF may be about 1200 MPa to about 2000 MPa. For example, the Young's modulus of the supporting film HMF may be about 1200 MPa to about 1500 MPa.

When shocks are applied from the outside, the support film having a Young's modulus of less than about 1200 MPa might not be capable of preventing the window from sagging, and accordingly, the shocks may be delivered to components located below the support film. A support film having a Young's modulus of greater than about 2000 MPa is not easy to repeat folding and unfolding. In one or more embodiments, the shock-absorbing panel SAP including a supporting film HMF having a Young's modulus of about 1200 MPa to about 2000 MPa may exhibit improved impact resistance. In some embodiments, the display device ED including the shock-absorbing panel SAP according to one or more embodiments may exhibit excellent or suitable reliability.

The support film HMF may include at least one of an amide-based resin, an ester-based resin, an ether-based resin, or a carbonate-based resin. The support film (HMF) including at least one of an amide-based resin, an ester-based resin, an ether-based resin, or a carbonate-based resin may have a Young's modulus of about 1200 MPa to about 2000 MPa. As used herein, a “˜˜based” resin may be considered as including a functional group of “˜˜”.

The buffer layer SRC may include at least one of an acryl-based resin, a urethane-based resin, or a silicone-based resin. The buffer layer SRC may have a Young's modulus of about 10 MPa to about 30 MPa. The buffer layer SRC including at least one of an acryl-based resin, a urethane-based resin, or a silicone-based resin may have a Young's modulus of about 10 MPa to about 30 MPa.

For example, the Young's modulus of the buffer layer SRC may be about 12 MPa to about 20 MPa. A buffer layer having a Young's modulus of less than about 10 MPa is vulnerable to shocks, and a buffer layer having a Young's modulus of greater than about 30 MPa is not able to absorb shocks, thereby damaging a display panel. In one or more embodiments, the shock-absorbing panel SAP and the display device ED including the buffer layer SRC having a Young's modulus of about 10 MPa to about 30 MPa may exhibit excellent or suitable impact resistance.

A thickness T1 of the support film HMF may be greater than a thickness T2 of the buffer layer SRC. The support film HMF having a relatively large Young's modulus may be provided to be thicker than the buffer layer SRC. The thickness T1 of the support film HMF may be about 35 μm to about 45 μm. A support film having a thickness of less than about 35 μm is vulnerable to shocks, and a support film having a thickness of greater than about 45 μm makes a display device thicker. A shock-absorbing panel SAP including a support film HMF having a thickness T1 of about 35 μm to about 45 μm, and a display device ED including the same, may exhibit excellent or suitable impact resistance.

The thickness T2 of the buffer layer SRC may be about 20 μm to about 30 μm. A buffer layer having a thickness of less than about 20 μm is not able to absorb shocks, and a buffer layer having a thickness of greater than about 30 μm makes a display device thicker. A shock-absorbing panel SAP including a buffer layer SRC having a thickness T2 of about 20 μm to about 30 μm, and a display device ED including the same, may exhibit excellent or suitable impact resistance.

FIG. 5 is a cross-sectional view showing one or more other embodiments of a shock-absorbing panel SAP-a. Compared to the shock-absorbing panel SAP shown in FIG. 4, the shock-absorbing panel SAP-a shown in FIG. 5 is different in that the shock-absorbing panel SAP-a further includes a sub support film RCT. In the description of FIG. 5, content overlapping the one described with reference to FIGS. 1 to 4 will not be described again, and differences will be mainly described.

The shock-absorbing panel SAP-a according to one or more embodiments may have a thickness T_Pa of about 60 μm to about 80 μm. For example, the thickness T_Pa of the shock-absorbing panel SAP-a including the sub support film RCT may be about 75 μm.

The shock-absorbing panel SAP-a may further include a sub support film RCT located on the support film HMF. The sub support film RCT may support the window WN. For example, the sub support film RCT may serve as a component to maximize or increase resistance to damage to the window WN.

The sub support film RCT may have a greater Young's modulus than the support film HMF and the buffer layer SRC. In the shock-absorbing panel SAP-a, the Young's modulus of the sub support film RCT may be the greatest, and the Young's modulus of the buffer layer SRC may be the least.

The sub support film RCT may include at least one of an imide-based resin or an aramid-based resin. Materials forming each of the support film HMF, the buffer layer SRC, and the sub support film RCT may be different.

The sub support film RCT including at least one of an imide-based resin or an aramid-based resin may have a Young's modulus of about 3000 MPa to about 4000 MPa. The Young's modulus of the sub support film RCT may be about 3000 MPa to about 4000 MPa. For example, the Young's modulus of the sub support film RCT may be about 3000 MPa to about 3500 MPa. A sub support film having a Young's modulus of less than about 3000 MPa may have low resistance to damage to a window, and a sub support film having a Young's modulus of greater than about 4000 MPa might not be repeatedly folded and unfolded easily. In one or more embodiments, the shock-absorbing panel SAP-a including the sub support film RCT having a Young's modulus of about 3000 MPa to about 4000 MPa may exhibit excellent or suitable impact resistance. In some embodiments, the display device ED including the shock-absorbing panel SAP-a may have increased reliability.

A thickness T3 of the sub support film RCT may be less than the thickness T1 of the support film HMF and the thickness T2 of the buffer layer SRC. In the shock-absorbing panel SAP-a, the thickness T3 of the sub support film RCT may be the smallest, and the thickness T1 of the support film HMF may be the largest.

The thickness T3 of the sub support film RCT may be about 5 μm to about μm. For example, the thickness T3 of the sub support film RCT may be about 10 μm. A sub support film having a thickness of less than about 5 μm has low resistance to cracking of a window, and a sub support film having a thickness of greater than about 15 μm is not easily repeatedly folded and unfolded. In one or more embodiments, the shock-absorbing panel SAP-a including a sub support film RCT having a thickness T3 of about 5 μm to about 15 μm may exhibit excellent or suitable impact resistance.

Table 2 below shows evaluation of Young's modulus, yield strain, and recovery rate in Comparative Examples and Examples. Table 2 shows results of evaluation using a universal testing machine (UTM). In Table 2, the yield strain indicates a strain when permanent deformation takes place, and the recovery rate indicates a recovery rate after 100 times of folding and unfolding.

Table 1 below shows a thickness of a support film and a thickness of a buffer layer included in Comparative Examples and Examples of Table 2. Comparative Examples C1 to C3 and Examples E1 to E3 are display devices that include a buffer layer and a support film, but do not include a sub support film. Comparative Example C4 and Examples E4 and E5 are display devices that include a buffer layer, a support film, and a sub support film. In Examples E1 to E3, a shock-absorbing panel corresponds to the shock-absorbing panel SAP shown in FIG. 4, and in Examples E4 and E5, a shock-absorbing panel corresponds to the shock-absorbing panel SAP-a shown in FIG. 5.

In Table 1, HM-1 to HM-3 are support films, RC-1 to RC-3 are sub support films, and SR-1 to SR-3 are buffer layers. In Examples E1 to E3, support films may each independently be the same as HM-2, and buffer layers are different. In Comparative Examples C2 and C3, support films may each independently be the same as HM-3, and buffer layers are different. In Example E4, Example E5, and Comparative Example C4, support films may each independently be the same as HM-2, buffer layers may each independently be the same as SR-1, and sub support films are different.

TABLE 1

| | Com- | | | | Com- | Com- | | | Com- |
|---|---|---|---|---|---|---|---|---|---|
| | parative | | | | parative | parative | | | parative |
| | Ex- | Ex- | Ex- | Ex- | Ex- | Ex- | Ex- | Ex- | Ex- |
| | ample | ample | ample | ample | ample | ample | ample | ample | ample |
| Item | C1 | E1 | E2 | E3 | C2 | C3 | E4 | E5 | C4 |
| Sub support | — | — | — | — | — | — | 10 | 10 | 10 |
| film | | | | | | | μm | μm | μm |
| thickness | | | | | | | RC-1 | RC-2 | RC-3 |
| Support film | 50 | 40 | 40 | 40 | 40 | 40 | 40 | 40 | 40 |
| thickness | μm | μm | μm | μm | μm | μm | μm | μm | μm |
| | HM-1 | HM-2 | HM-2 | HM-2 | HM-3 | HM-3 | HM-2 | HM-2 | HM-2 |
| Buffer layer | 25 | 25 | 25 | 25 | 25 | 25 | 25 | 25 | 25 |
| thickness | μm | μm | μm | μm | μm | μm | μm | μm | μm |
| | SR-1 | SR-1 | SR-2 | SR-3 | SR-1 | SR-2 | SR-1 | SR-1 | SR-1 |

Referring to Table 1, the support films of Comparative Examples C2 to C4 and Examples E1 to E5 have a thickness of about 40 μm, which satisfies the thickness range of the support film according to one or more embodiments. In one or more embodiments, the support film according to one or more embodiments may have a thickness of about 35 μm to about 45 μm.

The buffer layers of Comparative Examples C1 to C4 and Examples E1 to E5 have a thickness of about 25 μm, which satisfies the thickness range of the buffer layer according to one or more embodiments. In one or more embodiments, the buffer layer according to one or more embodiments may have a thickness of about 20 μm to about 30 μm.

The sub support films of Comparative Example C4, Example E4, and Example E5 have a thickness of about 10 μm, which satisfies the thickness range of the sub support film according to one or more embodiments. In one or more embodiments, the sub support film according to one or more embodiments may have a thickness of about 5 μm to about 15 μm.

TABLE 2

| | Comparative | | | | Comparative | Comparative | | | Comparative |
|---|---|---|---|---|---|---|---|---|---|
| | Example | Example | Example | Example | Example | Example | Example | Example | Example |
| Item | C1 | E1 | E2 | E3 | C2 | C3 | E4 | E5 | C4 |
| Young' | 530 | 950 | 944 | 1000 | 2930 | 2920 | 970 | 1100 | 1450 |
| modulus | | | | | | | | | |
| (MPa) | | | | | | | | | |
| Yield strain | 1.9 | 2.1 | 2.1 | 2 | 1.9 | 2 | 2.1 | 2.2 | 2.1 |
| (εγ, %) | | | | | | | | | |
| Recovery rate | 87 | 92 | 93 | 92 | 90 | 90 | 93 | 93 | 90 |
| (cycle, %) | | | | | | | | | |

Referring to Table 2, as compared with Comparative Examples C1 to C3, it is seen that Examples E1 to E3 have a Young's modulus of about 950 MPa, about 944 MPa, and about 1000 MPa. Compared with Comparative Example C4, it is seen that Examples E4 and E5 have a Young's modulus of about 970 MPa and about 1100 MPa. Examples E1 to E3 include a shock-absorbing panel including a buffer layer and a support film according to one or more embodiments, and the shock-absorbing panels of Examples E1 to E3 satisfy the Young's modulus range of the shock-absorbing panel according to one or more embodiments. Examples E4 and E5 include a shock-absorbing panel including a buffer layer, a support film, and a sub support film according to one or more embodiments, and the shock-absorbing panels of Examples E4 and E5 satisfy the Young's modulus range of the shock-absorbing panel according to one or more embodiments. The shock-absorbing panel according to one or more embodiments may have a Young's modulus of about 700 MPa to about 1200 MPa.

From Table 2, it is seen that Comparative Example C1 exhibits a Young's modulus of less than about 700 MPa, and Comparative Examples C2 and C3 exhibit a Young's modulus of greater than about 1200 MPa. It is seen that Comparative Examples C1 to C3 and Examples E1 to E3 exhibit similar yield strains. Compared with Comparative Examples C1 to C3, it is seen that Examples E1 to E3 exhibit high recovery rates. Accordingly, it is believed that Examples E1 to E3 will maintain reliability when folding and unfolding are repeated.

From Table 2, it is seen that Comparative Examples C4, Example E4, and Example E5 exhibit similar yield strains. Compared with Comparative Example C4, it is seen that Examples E4 and E5 exhibit high recovery rates. Accordingly, it is believed that Examples E4 and E5 will maintain reliability when folding and unfolding are repeated.

Table 3 below shows evaluation of Young's modulus, yield strain, and recovery rate in Comparative Examples and Examples. Table 3 shows results of evaluation using a universal testing machine (UTM), and Comparative Examples and Experimental Examples used samples having a size of about 1 cm×10 cm. Comparative Examples and Experimental Examples in Table 3 were single layers including a buffer layer, a support film, or a sub support film, and were used for the shock-absorbing panels of Tables 1 and 2. However, buffer layers used in Table 3 were thicker than the buffer layers in Tables 1 and 2. In Table 3, the thicknesses of the buffer layers, the support films, and the sub support films used in the evaluation are listed.

TABLE 3

| | Sub support film | | | Buffer layer | | | Support film | | |
|---|---|---|---|---|---|---|---|---|---|
| | Compar- | Exper- | Compar- | Exper- | Exper- | Compar- | Compar- | Exper- | Compar- |
| | ative | imental | ative | imental | imental | ative | ative | imental | ative |
| | Example | Example | Example | Example | Example | Example | Example | Example | Example |
| Item | RC-1 | RC-2 | RC-3 | SR-1 | SR-2 | SR-3 | HM-1 | HM-2 | HM-3 |
| Thickness | 10 | 10 | 10 | 100 | 100 | 100 | 50 | 40 | 40 |
| (μm) | | | | | | | | | |
| Young′ | 2500 | 3100 | 4500 | 13 | 11 | 31 | 700 | 1400 | 4500 |
| modulus | | | | | | | | | |
| (MPa) | | | | | | | | | |
| Yield strain | 2 | 2.1 | 1.8 | 1.8 | 2.1 | 1.9 | 2 | 2.2 | 1.9 |
| (εγ, %) | | | | | | | | | |
| Recovery rate | 93 | 90 | 89 | 93 | 95 | 90 | 83 | 94 | 92 |
| (cycle, %) | | | | | | | | | |

Referring to Table 3, the sub support film of Experimental Example RC-2 has a Young's modulus of about 3100 MPa, which satisfies the Young's modulus range of about 3000 MPa to about 4000 MPa of the sub support film according to one or more embodiments. It is seen that the sub support film of Comparative Example RC-1 has a Young's modulus of about 2500 MPa, which shows a Young's modulus of less than the lower limit of the Young's modulus range of about 3000 MPa. It is seen that the sub support film of Comparative Example RC-3 has a Young's modulus of about 4500 MPa, which shows a Young's modulus of greater than the upper limit of the Young's modulus range of about 4000 MPa.

The buffer layers of Experimental Examples SR-1 and SR-2 have Young's modulus of about 13 MPa and about 11 MPa, which satisfy the Young's modulus range of about 10 MPa to about 30 MPa of the buffer layer according to one or more embodiments. It is seen that the buffer layer of Comparative Example SR-3 has a Young's modulus of about 31 MPa, which is greater than upper limit of the Young's modulus range of about 30 MPa.

The support film of Experimental Example HM-2 has a Young's modulus of 1400 MPa, which satisfies the Young's modulus range of about 1200 MPa to about 2000 MPa of the support film according to one or more embodiments. The support film of Comparative Example HM-1 has a Young's modulus of 700 MPa which is less than the lower limit of the Young's modulus range of about 1200 MPa. The support film of Comparative Example HM-3 has a Young's modulus of about 4500 MPa, which is greater than the upper limit of the Young's modulus range of about 2000 MPa.

From Table 3, it is seen that the sub support films of Comparative Example RC-1, Comparative Example RC-3, and Experimental Example RC-2 exhibit similar yield strains. It is seen that the sub support films of Comparative Example RC-1, Comparative Example RC-3, and Experimental Example RC-2 exhibit similar recovery rates. Accordingly, it is believed that the sub support films of Comparative Example RC-1, Comparative Example RC-3, and Experimental Example RC-2 will maintain reliability when folding and unfolding are repeated.

From Table 3, it is seen that the buffer layers of Comparative Example SR-3, Experimental Example SR-1, and Experimental Example SR-2 exhibit similar yield strains. It is seen that the buffer layers of Comparative Example SR-3, Experimental Example SR-1, and Experimental Example SR-2 exhibit similar recovery rates. Accordingly, it is believed that the buffer layers of Comparative Example SR-3, Experimental Example SR-1, and Experimental Example SR-2 will maintain reliability when folding and unfolding are repeated.

From Table 3, it is seen that the support films of Comparative Example HM-1, Comparative Example HM-3, and Experimental Example HM-2 exhibit similar yield strains. It is seen that the support films of Comparative Example HM-3 and Experimental Example HM-2 exhibit similar recovery rates. Accordingly, it is believed that the support films of Comparative Example HM-3 and Experimental Example HM-2 will maintain reliability when folding and unfolding are repeated.

Table 4 below shows results of pen drop tests in the buffer layer of Experimental Examples. In Table 4, Experimental Examples are single-layered buffer layers. A pen of a certain weight was dropped from a height (e.g., a set or predetermined height) into the buffer layer, and the rebound time of the pen and the shock absorption rate in the buffer layer were recorded. The pen used in the pen drop tests has a ball size of about 0.3 φ (pi). Specifically, the diameter of the ball is 0.3 mm (i.e., 0.3 φ). The shock absorption rate was calculated from Equation 1 below.

Z₁=[(X₁−Y₁)/X₁]×100% Equation 1

In Equation 1, X₁ is a shock force measured in a state where a buffer layer is omitted, and Y₁ is a largest first shock force measured in a buffer layer from which the pen is dropped. Z₁ is the shock absorption rate.

In Table 4, Experimental Example SR-1 and Experimental Example SR-2 may each independently be the same buffer layers as Experimental Example SR-1 and Experimental Example SR-2 of Table 1. In Table 4, Experimental Example SR-1 and Experimental Example SR-2 have the same rebound time.

TABLE 4

| | Rebound | First shock force | Shock absorption |
|---|---|---|---|
| Item | time (sec) | (1st Force, N) | rate (%) |
| Experimental | 0.17 | 38.73 | 20.62 |
| Example SR-1 | | | |
| Experimental | 0.17 | 39.08 | 19.80 |
| Example SR-2 | | | |

Referring to Table 4, it is seen that the buffer layers of Experimental Examples SR-1 and SR-2 exhibit a similar level of shock absorption rate. For example, it is seen that the buffer layers of Experimental Examples SR-1 and SR-2 exhibit a shock absorption rate of about 19% or greater.

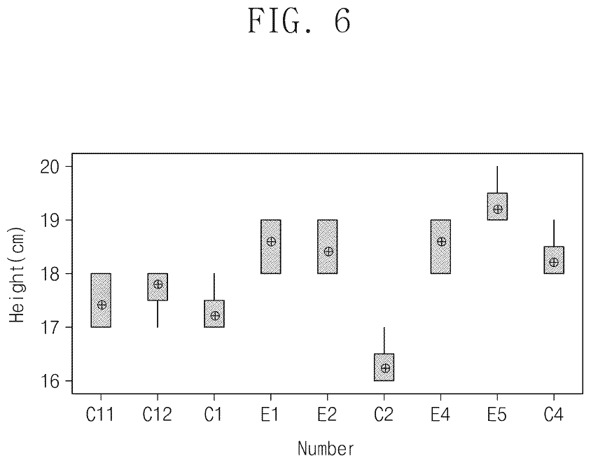

FIG. 6 shows results of pen drop tests in Comparative Examples and Examples. The results of FIG. 6 are obtained by dropping a pen of a weight from a height (e.g., a certain weight from a set or predetermined height) to an upper surface of a window, and observing and evaluating crack of the window and appearance of bright spots on a display panel. In FIG. 6, Comparative Examples and Examples are display devices including a display panel, a shock-absorbing panel, and a window. In Table 5, average values of the minimum height at which the crack of the window takes place in the pen drop tests are listed. The pen used in the pen drop tests has a ball size of 0.3 φ (pi).

C1, C2, C4, E1, E2, E4, and E5 of FIG. 6 may be respectively the same as Comparative Example C1, Comparative Example C2, Comparative Example C4, Example E1, Example E2, Example E4, and Example E5 of Table 2. C1, C2, C4, E1, E2, E4, and E5 of FIG. 6 are respectively described as Comparative Example C1, Comparative Example C2, Comparative Example C4, Example E1, Example E2, Example E4, and Example E5 in Table 5.

Comparative Example C11 includes a 50 μm thick HM-1 support film between a display panel and a window, and the shock-absorbing panel is a single layer. Comparative Example C12 includes an HM-1 support film that is about 75 μm thick, and the shock-absorbing panel is a single layer. The thickness of about 75 μm of the support film of Comparative Example C12 is the same as the total thickness of about 75 μm of the shock-absorbing panel in Comparative Example C4, Example E4, and Example E5.

TABLE 5

| | Compar- | Compar- | Compar- | | | Compar- | | | Compar- |
|---|---|---|---|---|---|---|---|---|---|
| | ative | ative | ative | | | ative | | | ative |
| | Example | Example | Example | Example | Example | Example | Example | Example | Example |
| Item | C11 | C12 | C1 | E1 | E2 | C2 | E4 | E5 | C4 |
| | — | — | | — | — | — | 10 μm | 10 μm | 10 μm |
| Sub | | | | | | | RC-1 | RC-2 | RC-3 |
| support | | | | | | | | | |
| film | | | | | | | | | |
| Support | 50 μm | 75 μm | 50 μm | 40 μm | 40 μm | 40 μm | 40 μm | 40 μm | 40 μm |
| film | HM-1 | HM-1 | HM-1 | HM-2 | HM-2 | HM-3 | HM-2 | HM-2 | HM-2 |
| Buffer | — | — | 25 μm | 25 μm | 25 μm | 25 μm | 25 μm | 25 μm | 25 μm |
| layer | | | SR-1 | SR-1 | SR-2 | SR-1 | SR-1 | SR-1 | SR-1 |
| Average | 17.4 | 17.8 | 17.2 | 18.6 | 18.4 | 16.2 | 18.6 | 19.2 | 18.2 |
| value | | | | | | | | | |
| (cm) | | | | | | | | | |

Referring to FIG. 6 and Table 5, it is seen that, as compared with Comparative Example C11, Comparative Example C12, Comparative Example C1, and Comparative Example C2, the minimum height at which the window crack takes place is relatively high in Comparative Example C4, Example E1, Example E2, Example E4, and Example E5. The cracking takes place when the pen is dropped from a relatively higher position, and thus it is seen that Comparative Examples C4, Example E1, Example E2, Example E4, and Example E5 exhibit excellent or suitable impact resistance. However, as shown in Table 2, Comparative Example C4 includes a shock-absorbing panel having a relatively very large Young's modulus, and accordingly, it might not be easy to repeat folding and unfolding.

In some embodiments, it is seen that a difference in minimum height at which the window crack takes place between Comparative Example C12 and Example E5 is about 1.5 cm or greater. Examples E1, E2, E4, and E5 include a shock-absorbing panel according to one or more embodiments. Accordingly, it is believed that a display device including the shock-absorbing panel according to one or more embodiments will exhibit excellent or suitable impact resistance.

Examples E1 and E2 include the same support film of HM-2, but include different buffer layers. Example E1 includes the buffer layer of SR-1, and Example E2 includes the buffer layer of SR-2. In Table 4 above, the buffer layers of SR-1 and SR-2 exhibited similar shock absorption rates. Accordingly, in FIG. 6 and Table 5, Example E1 including the buffer layer of SR-1 and Example E2 including the buffer layer of SR-2 are believed to have similar minimum heights at which the window crack takes place.

In FIG. 6 and Table 5, Comparative Example C2 includes the support film of HM-3, and in Table 3 above, the Young's modulus of the support film of HM-3 is about 4500 MPa. It is believed that in Comparative Example C2 including the support film having a very large Young's modulus, the drop height of the pen at which the window crack takes place is very low.

Table 6 below shows results of the pen drop tests in Comparative Examples and Examples. The results of FIG. 6 are obtained by dropping a pen of a weight from a height (e.g., a certain weight from a set or predetermined height) to an upper surface of a window, and observing and evaluating crack of the window at the point. The pen used in the pen drop tests has a ball size of 0.3 φ. In Table 6, Comparative Examples and Examples are display devices including a display panel, a shock-absorbing panel, and a window, and may each independently be the same as those of Comparative Examples and Examples in Table 5. In Table 6, the height shows the minimum value of drop height at which window crack takes place.

TABLE 6

| | Compar- | Compar- | | | | Compar- |
|---|---|---|---|---|---|---|
| | ative | ative | | | | ative |
| | Example | Example | Example | Example | Example | Example |
| Item | C11 | C12 | E1 | E2 | E5 | C4 |
| Sub | — | — | — | — | 10 μm | 10 μm |
| support | | | | | RC-2 | RC-3 |
| film | | | | | | |
| Support | 50 μm | 75 μm | 40 μm | 40 μm | 40 μm | 40 μm |
| film | HM-1 | HM-1 | HM-2 | HM-2 | HM-2 | HM-2 |
| Buffer | — | — | 25 μm | 25 μm | 25 μm | 25 μm |
| layer | | | SR-1 | SR-2 | SR-1 | SR-1 |
| Height | 16 | 13 | 18 | 17 | 19 | 19 |
| (cm) | | | | | | |

Referring to FIG. 6 and Table 5, it is seen that, as compared with Comparative Example C11 and Comparative Example C12, the minimum height at which the window crack takes place is high in Comparative Example C4, Example E1, Example E2, and Example E5. However, as shown in Table 2, Comparative Example C4 includes a shock-absorbing panel having a Young's modulus of greater than about 1200 MPa, and accordingly, it is not easy to repeat folding and unfolding.

Examples E1, E2, and E5 include the shock-absorbing panel according to one or more embodiments, and the shock-absorbing panel according to one or more embodiments may include a support film and a buffer layer. Accordingly, it is believed that a display device including the shock-absorbing panel according to one or more embodiments will exhibit excellent or suitable impact resistance.

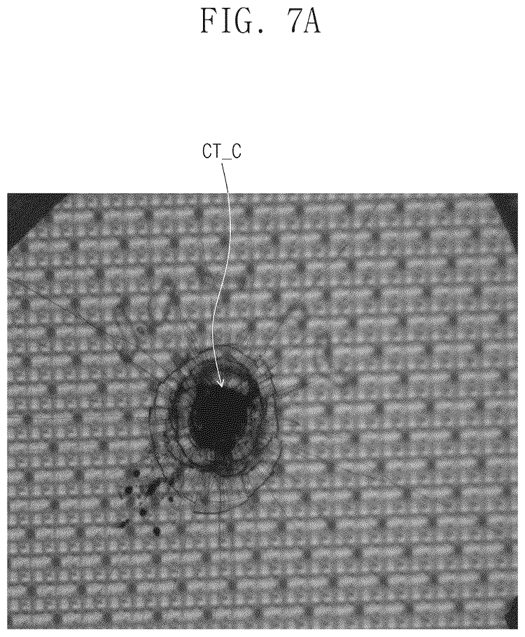

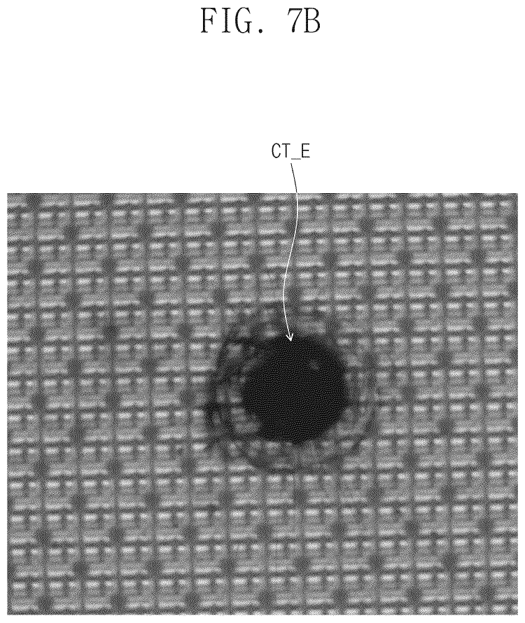

FIGS. 7A and 7B are microscopic images of windows in Comparative Examples and Examples. FIG. 7A is a microscopic image of Comparative Example C12 after pen drop tests. FIG. 7B is a microscopic image of Example E5 after pen drop tests.

Referring to FIG. 7A, it is seen that in Comparative Example C12, cracks also took place in the region around region CT_C in which the window was cracked. It is seen that in Comparative Example C12, a large area of the window was damaged, and the extent of damage was significant.

Referring to FIG. 7B, it is seen that, in Example E5, cracks hardly took place in the region around region CT_E in which the window was cracked. Compared with Comparative Example C12 of FIG. 7A, it is seen that in Example E5 of FIG. 7B, a relatively narrow area of the window was damaged, and the extent of damage was insignificant. Example E5 includes the shock-absorbing panel according to one or more embodiments, and the shock-absorbing panel according to one or more embodiments may include a buffer layer, a support film, and a sub support film. Accordingly, it is believed that a display device including the shock-absorbing panel according to one or more embodiments may exhibit improved impact resistance.

A display device according to one or more embodiments may include a shock-absorbing panel located between a display panel and a window. The shock-absorbing panel may include a support film and a buffer layer located below the support film. In some embodiments, the shock-absorbing panel may further include a sub support film located above the support film. In one or more embodiments, the shock-absorbing panel may have a Young's modulus of about 700 MPa to about 1200 MPa. The shock-absorbing panel having a Young's modulus of about 700 MPa to about 1200 MPa may minimize, prevent, or reduce damage to the window and the display panel from external shocks. Accordingly, the shock-absorbing panel according to one or more embodiments may exhibit excellent or suitable impact resistance. In some embodiments, the display device including the shock-absorbing panel according to one or more embodiments may exhibit excellent or suitable reliability.

A display device according to one or more embodiments includes a shock-absorbing panel having a multilayer, and may thus exhibit excellent or suitable folding properties and improved impact resistance.

Although the present disclosure has been described with reference to various embodiments, it will be understood that the present disclosure should not be limited to these embodiments, and that one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, with functional equivalents thereof to be included therein.

What is claimed is:

1. A display device comprising:
a display panel;
a shock-absorbing panel above the display panel, having a Young's modulus of about 700 MPa to about 1200 MPa with respect to a strain of about 0.025% to about and comprising a support film, and a buffer layer below the support film; and
a window above the shock-absorbing panel, and comprising a glass substrate.

2. The display device of claim 1, wherein the support film has a greater Young's modulus than the buffer layer.

3. The display device of claim 1, wherein, with respect to the strain, the support film has a Young's modulus of about 1200 MPa to about 2000 MPa.

4. The display device of claim 1, wherein, with respect to the strain, the buffer layer has a Young's modulus of about 10 MPa to about 30 MPa.

5. The display device of claim 1, wherein the support film is thicker than the buffer layer.

6. The display device of claim 1, wherein the buffer layer has a thickness of about 20 μm to about 30 μm.

7. The display device of claim 1, wherein the support film has a thickness of about 35 μm to about 45 μm.

8. The display device of claim 1, wherein the shock-absorbing panel further comprises a sub support film above the support film.

9. The display device of claim 8, wherein the sub support film has a greater Young's modulus than the support film and the buffer layer.

10. The display device of claim 8, wherein, with respect to the strain, the sub support film has a Young's modulus of about 3000 MPa to about 4000 MPa.

11. The display device of claim 8, wherein the sub support film is thinner than the support film and the buffer layer.

12. The display device of claim 8, wherein the sub support film has a thickness of about 5 μm to about 15 μm.

13. The display device of claim 1, wherein the shock-absorbing panel has a thickness of about 60 μm to about 80 μm.

14. The display device of claim 1, wherein the window has a thickness of about 10 μm to about 300 μm.

15. The display device of claim 1, further comprising a protection layer above the window,
wherein the protection layer comprises at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cyclic olefin copolymer (COC).

16. A display device comprising:
a display panel;
a shock-absorbing panel above the display panel, having a Young's modulus of about 700 MPa to about 1200 MPa with respect to a strain of about 0.025% to about and comprising:
a support film comprising at least one of an amide-based resin, an ester-based resin, an ether-based resin, or a carbonate-based resin; and
a buffer layer comprising at least one of an acryl-based resin, a urethane-based resin, or a silicone-based resin, and below the support film; and
a window above the shock-absorbing panel and comprising a glass substrate.

17. The display device of claim 16, wherein the support film has a greater Young's modulus than the buffer layer, and is thicker than the buffer layer.

18. The display device of claim 16, wherein the shock-absorbing panel further comprises a sub support film above the support film and having a greater Young's modulus than the support film and the buffer layer.

19. The display device of claim 18, wherein the sub support film comprises at least one of an imide-based resin or an aramid-based resin.

20. The display device of claim 16, wherein the display device is folded to have a radius of curvature of about 1 mm to about 5 mm with respect to at least one folding axis.
